(19) United States
(12) Patent Application Publication
(10) Pub. No.: US 2026/0293341 A1
(43) Pub. Date: Sep. 24, 2026

(54) OPTICAL PACKAGE WITH STACKED INTEGRATED FILTERS

(71) Applicant: TEXAS INSTRUMENTS INCORPORATED, Dallas, TX (US)

(72) Inventors: Priya Manchiraju, Dallas, TX (US); Steven Kummerl, Carrollton, TX (US); Karthik Rajagopal, Plano, TX (US); Rujuta Munje, Mckinney, TX (US); Bailey Cordell, Plano, TX (US); Michael Yu, Plano, TX (US); Randall Woodrum, Rowlett, TX (US)

(21) Appl. No.: 19/085,888

(22) Filed: Mar. 20, 2025

(51) Int. Cl. H10F 39/00; G02B 5/20

(52) U.S. Cl. CPC H10F 39/8053; H10F 39/024; H10F 39/804; H10F 39/806; G02B 5/20; H10F 39/811

(57) ABSTRACT

An optical filter package may include a glass plate having a first surface and a second surface opposite to the first surface, in which the first surface has a first filter, and the second surface has a second filter. The optical filter package may include a semiconductor die including a light sensor and having a third surface and a fourth surface opposite to the third surface, in which at least a portion of the third surface has a third filter. The optical filter package may further include an optically transparent adhesive in contact with the second surface of the glass plate and the third surface of the semiconductor die.

### BACKGROUND

A semiconductor die having a light sensor is an integrated chip (IC) that can detect the intensity of ambient light in various environments. It typically consists of a photodetector, which converts light into an electrical signal, along with associated circuitry to process the electrical signals and output relevant data. It is often integrated into broader system-on-chip (SoC) solutions, ensuring minimal space usage while delivering reliable performance for automatic brightness control and other light-sensitive applications. Such semiconductor dies are often used in light sensor systems to adjust brightness of screens in electronic devices such as smartphones, tablets, and automotive displays, optimizing visibility and power consumption.

### SUMMARY

In an example, an optical filter package includes a semiconductor die having a light sensor. A glass plate with different filters on opposing surfaces is attached to the semiconductor die with an optically transparent adhesive. At least a portion of a surface of the semiconductor die in contact with the optically transparent adhesive has one or more other filters thereon.

In another example, an integrated optical filter package includes a semiconductor die including a light sensor. The semiconductor die is attached with an adhesive to a substrate. A glass plate with different filters on opposing surfaces is attached to the semiconductor die with an optically transparent adhesive. At least a portion of a surface of the semiconductor die in contact with the optically transparent adhesive has one or more other filters thereon. An optically opaque mold compound peripherally surrounds the glass plate and the semiconductor die such that one of the surfaces of the glass plate is exposed to ambient light. The semiconductor die is electrically coupled to the substrate by wire-bonds.

In another example, a method for making an integrated optical filter package includes attaching a film of optically transparent adhesive to a glass wafer having different filters on opposing surfaces, dicing the glass wafer into individual glass plates, each glass plate having a portion of the film of optically transparent adhesive, and placing a glass plate on a top surface of an assembly comprising a semiconductor die having a light sensor such that a surface of the semiconductor die next to the glass plate includes at least one other filter attached thereto, and the portion of the film of optically transparent adhesive is between the glass plate and the surface of the semiconductor die. Pressure may be subsequently applied on an exposed surface of the glass plate and temperature may be increased until the portion of the film of optically transparent adhesive is cured. The semiconductor die may be electrically bonded to a substrate, for example, by wire bonding. An optically opaque mold compound may be applied along a periphery of the semiconductor die and the glass plate and subsequently cured.

### BRIEF DESCRIPTION OF THE DRAWINGS

Examples will be readily understood by the following detailed description in ‎conjunction with the accompanying drawings. To facilitate this description, like reference ‎numerals designate like elements. Aspects are illustrated by way of ‎example, and not by way of limitation, in the figures of the accompanying drawings.‎

FIG. 1 is a simplified diagram illustrating a cross-sectional view of an example optical filter package with stacked integrated filters.

FIGS. 2A -2B are simplified diagrams illustrating a plan view and a cross-sectional view respectively, of an example optical filter package with stacked integrated filters.

FIG. 3 is a simplified side view of a glass plate used in an example optical filter package with stacked integrated filters.

FIG. 4 is a simplified side view of a glass plate used in an example optical filter package with stacked integrated filters.

FIG. 5 is a simplified side view of a glass plate used in an example optical filter package with stacked integrated filters.

FIGS. 6A-6C are simplified views of example glass plates used in an example optical filter package with stacked integrated filters.

FIG. 7 is a simplified side view of a glass plate used in an example optical filter package with stacked integrated filters.

FIG. 8 is a simplified side view of a glass plate used in an example optical filter package with stacked integrated filters.

FIG. 9 is a simplified plan view of a glass plate used in an example optical filter package with stacked integrated filters.

FIG. 10 is a simplified plan view of some components of an example optical filter package with stacked integrated filters.

FIG. 11 is a simplified diagram illustrating a cross-sectional view of an example optical filter package with stacked integrated filters.

FIG. 12 is a simplified diagram illustrating a cross-sectional view of an example optical filter package with stacked integrated filters.

FIG. 13 is a simplified diagram illustrating a cross-sectional view of an example optical filter package with stacked integrated filters.

FIG. 14 is a simplified diagram illustrating a cross-sectional view of an example optical filter package with stacked integrated filters.

FIG. 15 is a simplified flow diagram illustrating example operations associated with manufacturing an optical filter package with stacked integrated filters.

### DETAILED DESCRIPTION

For purposes of illustrating the examples described herein, it is important to understand certain terminology and operations of semiconductor packages. The following foundational information may be viewed as a basis from which various technical aspects described in the present disclosure may be properly explained. Such information is offered for purposes of explanation only and, accordingly, should not be construed in any way to limit the broad scope of the technology presented herein and its potential applications.

In the following detailed description, various aspects of the illustrative implementations may be described using terms commonly employed by those skilled in the art to convey the substance of their work to others skilled in the art.

The term “integrated circuit” (also referred to as IC) means a circuit that is integrated into a monolithic semiconductor or analogous material. A “die” or “semiconductor die” refers to a piece of semiconductor or analogous material (e.g., silicon, gallium nitride, etc.), that contains an IC or other electronic components. The terms “package” and “IC package” are synonymous, as are the terms “die” and “IC die.” Note that the terms “chip,” “die,” and “IC die” may be used interchangeably herein.

The terms “circuit” and “circuitry” mean one or more passive and/or active electrical and/or electronic components that are arranged to cooperate with one another to provide a desired function. The terms also refer to analog circuitry, digital circuitry, hard wired circuitry, optical circuitry, programmable circuitry, microcontroller circuitry and/or any other type of physical hardware, electrical and/or electronic component.

The term “package substrate” or “substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., PCB), glass, ceramic, silicon, silicon carbide, aluminum nitride, alumina, etc. In addition, as used herein, a package substrate may refer to a substrate that includes buildup layers (e.g., ABF layers). Further, the package substrate may comprise a conductive leadframe with leadfingers. In yet other examples, the package substrate may comprise disjointed conductive pieces (e.g., die pad, bond pads, leadfingers, etc.) enmeshed in a dielectric material, such as mold compound and polyimide films. Packages may also include organic or inorganic passivation layers between the bare die and the substrate.

The term “filter” or “optical filter” is used to refer to a component or material designed to selectively transmit, block, or modify the intensity, wavelength and angular distribution of light that passes through it. Filter function by utilizing various optical mechanisms such as absorption, reflection, diffraction, or transmission. Optical filters can include color filters (e.g., colored glass), interference coatings, diffusers, micro-holes and microlenses. For example, diffuser filters scatter light to produce uniform or diffuse patterns; microhole filters can filter specific light wavelengths, intensity, or angle (e.g., direction) based on hole size and spacing; color filters may allow only light of a specific wavelength range to pass through while blocking or absorbing light in other wavelengths.

The term “light” as used herein refers to electromagnetic waves with wavelength ranging approximately between 200 nanometers and 1 millimeter. It includes the near-ultraviolet, visible optical spectrum (e.g., light visible to the average human eye) and infrared (IR) wavelength ranges. The optical spectrum has the following approximate wavelength ranges for different colors and IR: near ultraviolet: 200-400 nanometers; violet: 380–450 nanometers; blue: 450–495 nanometers; green: 495–570 nanometers; yellow: 570–590 nanometers; orange: 590–620 nanometers; red: 620–750 nanometers; IR: 750 nanometers to 1 millimeter. Thus, for example, where reference is made to a green color filter, it may be understood that the color filter allows light within the wavelength range of approximately 495-570 nanometers to pass through, while absorbing or blocking light outside this range. Likewise, an IR filter allows light in the wavelength range of approximately 750 nanometers to 1 millimeter to pass through, while absorbing or blocking light in other wavelengths. A near-ultraviolet filter may allow light in the wavelength range of approximately 200 nanometers to 400 nanometers to pass through, while absorbing or blocking light in other wavelengths.

The terms “substantially,” “close,” “approximately,” “near,” and “about,” generally refer to being within +/- 20% of a target value (e.g., within +/- 5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/- 5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments. “Embodiment,” “aspect” and “example” are used interchangeably herein to describe particular versions, alternatives, constructions, implementations, configurations, arrangements, methods, processes and the like.

Where the disclosure or claims recite “a,” “an,” “a first,” or “another” element, or the equivalent thereof, it should be interpreted to include one or more than one such element, neither requiring nor excluding two or more such elements. Furthermore, the terms “comprising,” “including,” “having,” and the like, as used with respect to embodiments of the present disclosure, are synonymous. To the extent that the term “includes” is used in either the detailed description or the claims, such term is intended to be inclusive in a manner similar to the term “comprising” as “comprising” is interpreted when employed as a transitional word in a claim. The term “based on” is interpreted to mean based at least in part on.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer over or under another layer may be directly in contact with the other layer or may have one or more intervening layers. Moreover, one layer between two layers may be directly in contact with one or both of the two layers or may have one or more intervening layers. Similarly, unless explicitly stated otherwise, one feature between two features may be in direct contact with the adjacent features or may have one or more intervening layers.

The term “between,” when used with reference to measurement ranges, is inclusive of the ends of the measurement ranges.

Although certain elements may be referred to in the singular herein, such elements may include multiple sub-elements. For example, “an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale. In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using suitable characterization tools such as scanning electron microscopy (SEM), transmission electron microscope (TEM), or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging. All such non-idealized and realistic possibilities are intended to be included in the scope of the various examples described herein.

Note that in the figures, various components are shown as aligned (e.g., at respective interfaces) merely for ease of illustration; in actuality, some or all of them may be misaligned. In addition, there may be other components, such as bond-pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments. Note also that in cross-sectional views, some components shown as touching each other need not touch each other at all; they may be in different planes with intervening material removed. Thus, unless specifically described as being conductively coupled, surfaces shown to be touching each other may, in fact, have intervening material that is not shown for ease of illustration.

Further, unless otherwise specified, the structures shown in the figures may take any suitable form or shape according to material properties, fabrication processes, and operating conditions.

For convenience, if a collection of drawings designated with different letters are present (e.g., FIGS. 10A-10C), such a collection may be referred to herein without the letters (e.g., as “FIG. 10”). Similarly, if a collection of reference numerals designated with different letters are present (e.g., 112a-112e), such a collection may be referred to herein without the letters (e.g., as “112”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

Optical filters are used in light sensor systems to selectively transmit, block, or alter the wavelength, angle, and intensity (among other characteristics) of light, allowing the sensor to focus on certain parts of the light spectrum and/or capture optical energy in particular ways. These filters can help enhance the sensor's accuracy by eliminating unwanted light, improving the sensor's ability to detect specific light sources or environmental conditions. Common types of optical filters include bandpass filters, which allow only a narrow range of wavelengths to pass through, long-pass or short-pass filters, which block wavelengths shorter or longer than a specified cutoff, diffusers that alter the angle of incident light, and so on.

Typically, filters are tailored to specific applications. For example, light sensor systems that are used in applications to detect specific colors have filters that remove wavelengths other than the wavelength of the color to be detected. Some applications require infrared light to be removed, and such sensors have infrared light filters therein. In other applications, the sensor systems are specifically for detecting heat, and sensors in such applications include filters that filter out all except infrared wavelengths. In another application for sensing fingerprints, the filter may include pinholes (i.e., micro-holes) for partially blocking or collimating light falling on the sensor. In rare instances, more than one filter may be present as separate components coupled within one sensor system.

Semiconductor dies with light sensors are commonly used in the sensor industry. Some sensor systems include one or two filters integrated into a package that houses the semiconductor die. In some such optical packages, the surface of the semiconductor die having the light sensor is exposed to incident light. The semiconductor die may have a filter, such as a microlens for focusing or diffusing light, or a color filter for filtering particular wavelengths of light. In some other such optical packages, a glass member with an integrated infrared filter, or color filter, or micro-holes may be located on the surface of the semiconductor die.

Currently, such sensor systems with integrated filters are limited in filter combinations due to materials, assembly, and/or manufacturing limitations. For example, wafer-scale production can improve manufacturing efficiency, but the need to wirebond the semiconductor die for electrical connectivity makes wafer scale attachment impossible from a practical standpoint for these optical packages. Using flip-chip connections is not feasible either, as the active area of the die must be exposed to incident light, facing away from the package substrate, whereas flip-chip connectivity requires the semiconductor die to be assembled with its active region facing the substrate. In addition, package level assembly can be prone to inefficiencies. Attaching optical filters separately on the semiconductor die in such scenarios can be cumbersome and may require special handling (e.g., to ensure alignment), which can be cost prohibitive. Because of such additional costs and complexities, while optical sensors may be integrated with one or two filters in the package, additional filters are placed off the device entirely, depending on the end application.

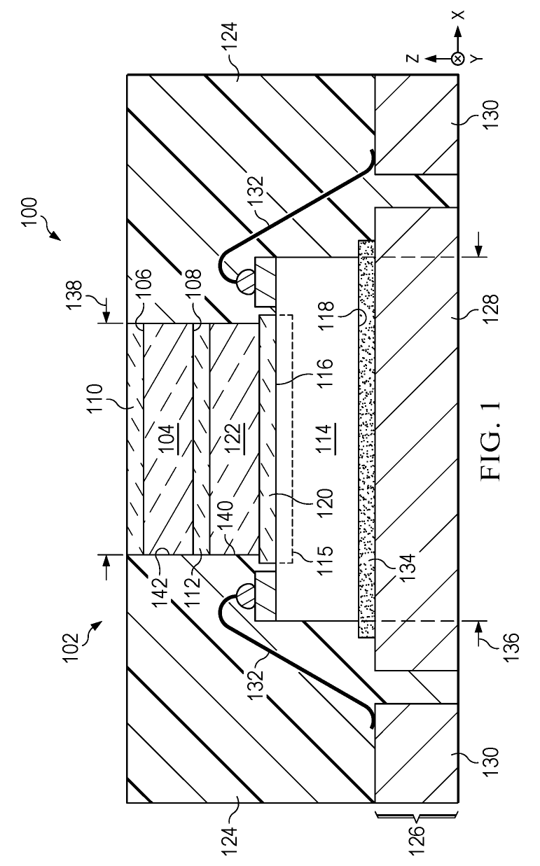

FIG. 1 is a simplified diagram illustrating a cross-sectional view of an example optical filter package 100 used in a light sensor system 102. Optical filter package 100 comprises a glass plate 104 having a first surface 106 and a second surface 108 opposite to first surface 106. First surface 106 has a first filter 110, and second surface 108 has a second filter 112 different from first filter 110. Optical package 100 further includes a semiconductor die 114 that includes at least one light sensor 115. Light sensor 115 comprises one or more electrical or photonic circuits to detect, measure, and/or otherwise manipulate light. Semiconductor die 114 has a third surface 116 proximate to second surface 108 and a fourth surface 118 opposite to third surface 116. At least a portion of third surface 116 has a color filter 120. An optically transparent adhesive 122 is in contact with second surface 108 of glass plate 104 and third surface 116 of semiconductor die 114. In some examples, color filter 120 may not have a uniform thickness across third surface 116; in such cases, optically transparent adhesive 122 may conform to the topological variations resulting therefrom.

An optically opaque mold compound 124 peripherally surrounds glass plate 104 and semiconductor die 114 such that first filter 110 is exposed. A substrate 126 comprises a first region 128 proximate to fourth surface 118 of semiconductor die 114. Substrate 126 further comprises a second region 130 to electrically couple to semiconductor die 114 by wire-bonds 132. An adhesive 134 is in contact with (e.g., bonds, adheres, etc.) substrate 126 and fourth surface 118 of semiconductor die 114. In some examples, adhesive 134 is a die attach adhesive comprising epoxy or polyimide. In some examples, as in the one shown in the figure, a first footprint 136 of semiconductor die 114 may be greater than a second footprint 138 of glass plate 104. In addition, a peripheral edge 140 of optically transparent adhesive 122 may be substantially flush with another peripheral edge 142 of glass plate 104 (e.g., footprint of optically transparent adhesive 122 may be approximately equal to footprint 138 of glass plate 104).

In the example shown, optical filter package 100 is a quad flat no lead (QFN) package or dual flat no leads (DFN) package, exposing regions 128 and 130 of substrate 126 opposite to first surface 106 of glass plate 104. In some such examples, first region 128 may comprise a die pad (e.g., thermal die pad) and second region 130 may comprise bond pads. Various other package formats may also be used without departing from the scope of the examples described herein. Substrate 126 may be mounted to a PCB such that regions 128 and 130 of substrate 126 opposite to first surface 106 of glass plate 104 are electrically and/or thermally bonded to the PCB. During operation, light may be incident on first surface 106 and detected suitably by circuits in semiconductor die 114.

In various example implementations, glass plate 104 is a homogeneous glass material not comprised of separate fibers such as in glass impregnated FR4. Examples of the homogeneous glass material of glass plate 104 includes borosilicate glass, fused silica, aluminosilicate glass, soda lime glass, etc. In various embodiments, the material of glass plate 104 may be selected to withstand high temperatures for curing polymeric materials in optical filter package 100, such as optically transparent adhesive 122, optically opaque mold compound 124, or adhesive 134. Optically transparent adhesive 122 may comprise commercially available epoxy, B-stage, optical die attach film (ODAF), film over wire material (FOW), or other optically transparent polymeric adhesive material. Optically opaque mold compound 124 may comprise an epoxy material compatible with optically transparent adhesive 122 (e.g., without chemically reacting therewith, bleeding thereinto, etc.). In various embodiments, optically opaque mold compound 124 may be selected from commercially available off-the-shelf materials that are typically used in non-optical packages based on particular needs, for example, to minimize costs.

In one specific example, first filter 110 may comprise a diffuser filter and second filter 112 may comprise a micro-hole filter, or vice versa. In another specific implementation, first filter 110 may comprise a diffuser filter and second filter 112 may comprise an infrared filter, or vice versa. In yet another specific implementation, first filter 110 may comprise a micro-hole filter and second filter 112 may comprise an infrared filter, or vice versa. Color filter 120 may filter one or more colors. Color filter 120 may vary in thickness depending on the color of light it is configured to filter and the amount of light it is configured to transmit or absorb. In various examples, any one or more of color filter 120 may vary in thickness between 0.5 microns and 15 microns. For example, a deep red filter might be thicker than a light yellow filter to block the same amount of light. The material for a green color filter may be different from that of a red color filter. In some examples, color filter 120 may comprise more than one coating of a material or coatings of different materials depending on the color to be filtered, or the intensity of light to attenuate or transmit.

In addition, the material and thickness of the other optically transparent materials, such as glass plate 104, optically transparent adhesive 122, first filter 110, second filter 112, and color filter 120 as well as the type of filters in first filter 110 and second filter 112 may be selected according to desired optical requirements such as the properties of light incident on third surface 116 of semiconductor die 114. For example, the thicknesses and materials of glass plate 104, optically transparent adhesive 122, first filter 110, second filter 112, and color filter 120 as well as the type of first filter 110 and second filter 112 may be selected to enable light within a specific range of wavelengths and having a specific range of intensities to be incident upon third surface 116 within a specific range of angles such that the light is detected by a light sensor in semiconductor die 114. In other words, optical properties and thicknesses of optically transparent adhesive 122, first filter 110, second filter 112, and glass plate 104 may be selected to enable measurements of wavelength, intensity, and angle of light by semiconductor die 114 to be within respective predetermined ranges. For example, a desired range of wavelength may be between 300-1000 nanometers; a desired range of intensity may be between 100 microlux - 100000 lux. Light having optical properties outside the specific ranges may not be detected by the light sensor in some such examples. In some other examples, the selection of thickness and materials of the various components may be based on additional factors, such as thermo-mechanical reliability (e.g., mitigation of coefficient of thermal expansion (CTE) mismatch, reduction of warping during manufacturing and operation, cost, form factor (e.g., thicknesses selected such that package height is within a specific range), etc.

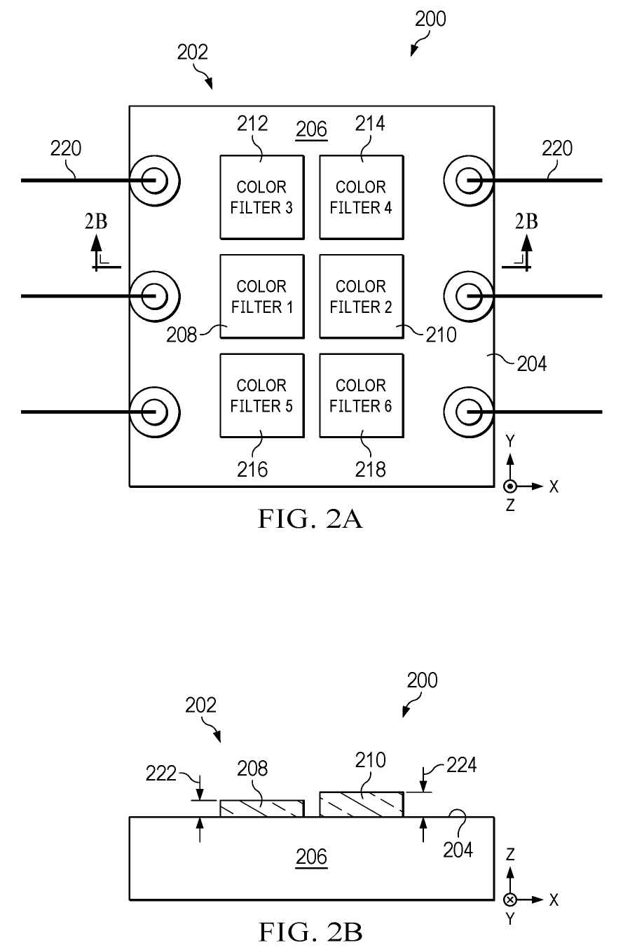

FIG. 2A is a simplified diagram illustrating a plan view of an example optical filter package 200 used in a light sensor system 202. Optical filter package 200 is substantially similar to optical filter package 100. Note that in the view shown, not all components of optical filter package 200 are shown. For example, the glass plate, optically transparent adhesive, optically opaque mold compound and substrate are not shown merely for ease of explanation and not as limitations. A third surface 204 of a semiconductor die 206 including a light sensor (not shown for ease of illustration) in optical filter package 200 may have thereon a plurality of color filters 208-218. In various examples, color filters 208-218 may be deposited over third surface 204 in one or more steps.

In one specific example, color filter 208 may be a green color filter; color filter 210 may be a blue color filter; color filter 212 may be a yellow color filter; and so on. In the example view shown, color filters 208, 210, 212, 214, 216 and 218 are rectangular and arranged in an array, each one being separated from the others. In other example, other configurations may be implemented. For example, each color filter 208-218 may be hexagonal in shape, and may be collectively arranged in a manner of a planar beehive, with adjacent edges touching each other. In another example, each color filter 208-218 may be circular in shape and irregularly dispersed on third surface 204. In yet another example, color filter 208 may be circular and other color filters 210-218 may be concentrically annular around color filter 208. In addition, although six color filters 208-218 are shown, such is merely for ease of illustration; any number of color filters may be used in optical filter package 200 without departing from the scope of the examples. Various other such configurations may be used without departing from the scope of the examples.

Note that wire-bonds 220 are shown on peripheral edges of semiconductor die 206. However, such is merely for ease of illustration; in other examples, wire-bonds 220 may be arranged on all four sides of semiconductor die 206.

A sectional view of optical filter package 200 along the plane indicated is shown in FIG. 2B. Color filters 208-218 may be of different thicknesses in various examples. In the view shown, color filter 208 has a first thickness 222 and color filter 210 has a second thickness 224, which is greater than first thickness 222. The range of thickness of different color filters may vary between 50 nanometers and 500 nanometers, in some examples. Each color filter may have different number of layers of coatings in some examples. In one example, color filter 208 may comprise 10 coatings, each coating varying between 0.2 micrometer – 1 micrometer in thickness, so that first thickness 222 may vary between approximately 2 micrometers and 10 micrometers; color filter 210 may comprise 20 coatings, each coating varying between 0.1 micrometer and 0.5 micrometer in thickness, so that second thickness 224 may vary between approximately 2-10 micrometers. In some such examples, first thickness 222 may be approximately 2 micrometers and second thickness 224 may be 10 micrometers. In another such example, first thickness 222 may be approximately 5 micrometers and second thickness 224 may be 7 micrometers. Other color filters 212-218 may have correspondingly different thicknesses and/or number of layers of coatings. Each color filter 208-218 may also be made of a different material, depending on the particular optical properties desired.

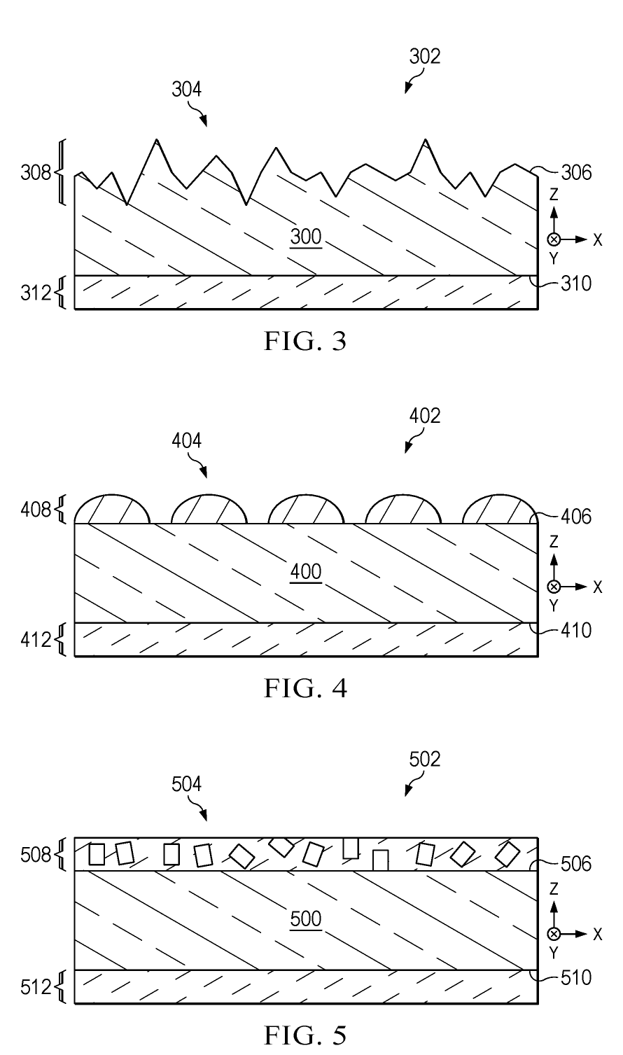

FIG. 3 is a simplified side view of a glass plate 300 used in an optical filter package 302 of a light sensor system 304. Glass plate 300 is substantially similar to glass plate 104 in various examples. In the example shown, a first surface 306 of glass plate 300 includes a diffuser filter 308. Diffuser filter 308 may be etched on first surface 306 such that light falling in any specific angle may be scattered into multiple angles as it is transmitted through glass plate 300. The etching may comprise a random pattern of holes, lines and other shapes based on the desired optical characteristics of the transmitted light. A second surface 310 of glass plate 300 may comprise another filter, for example, IR filter 312. In the example shown, IR filter 312 may comprise a coating on second surface 310. In one example, the coating may be sputtered on glass plate 300. In various examples, a glass wafer may be processed to generate diffuser filter 308 and IR filter 312 on opposing surfaces. Subsequently, after further processing in various examples, the glass wafer may be diced into individual ones of glass plate 300 and each such glass plate 300 may be attached to a semiconductor die having a light sensor, such as semiconductor die 114. In some other examples, the relative locations of the light filters may be reversed so that IR filter 312 is on first surface 306 and diffuser filter 308 is on second surface 310.

In some applications, light incident on semiconductor die 114 may be required to be at unspecified angles within the IR spectrum of light. Such may be the case where a light sensor in semiconductor die 114 may be prone to errors if incident light falls at specific angles, or the light intensity varies substantially across the surface of semiconductor die 114. In some such applications, glass plate 300 with the optical filters as described herein may be used suitably. In some applications, the choice to place IR filter 312 on first surface 306 or second surface 310 may depend on the material, type, or effectiveness of IR filter 312 relative to the angle of incident light. For example, some IR filters may be more effective if the incident light is diffused; in such cases, IR filter 312 may be located on second surface 310 so that light reaching IR filter 312 is after diffusion by diffuser filter 308 on first surface 306.

FIG. 4 is a simplified side view of a glass plate 400 used in an optical filter package 402 of a light sensor system 404. Glass plate 400 is substantially similar to glass plate 104 in various examples. In the example shown, a first surface 406 of glass plate 400 includes a diffuser filter 408. Diffuser filter 408 may comprise droplets or other shapes of opaque or translucent material deposited on first surface 406 such that light falling in any specific angle may be scattered into multiple angles as it is transmitted through glass plate 400. The droplets may be in any random pattern in some examples; in other examples, the droplets may be in a regular array deposited via screen printing or other such additive manufacturing processes. The pattern and shape of the deposited material may be based on the desired optical characteristics of the transmitted light. A second surface 410 of glass plate 400 may comprise another filter, for example, IR filter 412. IR filter 412 may be substantially similar to IR filter 312. In various examples, a glass wafer may be processed to generate diffuser filter 408 and IR filter 412 on opposing surfaces. Thereafter, the glass wafer may be diced into individual ones of glass plate 400 and each such glass plate 400 may be attached to a semiconductor die having a light sensor, such as semiconductor die 114. In some other examples, the relative locations of the light filters may be reversed so that IR filter 412 is on first surface 406 and diffuser filter 408 is on second surface 410.

FIG. 5 is a simplified side view of a glass plate 500 used in an optical filter package 502 of a light sensor system 504. Glass plate 500 is substantially similar to glass plate 104 in various examples. In the example shown, a first surface 506 of glass plate 500 includes a diffuser filter 508. Diffuser filter 508 may comprise a film including a suspension of opaque or translucent material therein, deposited on first surface 506 such that light falling in any specific angle may be scattered into multiple angles as it is transmitted through glass plate 500. The suspended solids within the film may be of any suitable size and shape, and may be in a random pattern. In some examples, such diffuser films may be coated on first surface 506 using any suitable method according to the desired optical characteristics of the transmitted light, such as a process involving spin-coating, ultraviolet cure, and/or annealing. A second surface 510 of glass plate 500 may comprise another filter, for example, IR filter 512. IR filter 512 may be substantially similar to IR filter 312. In various examples, a glass wafer may be processed to generate diffuser filter 508 and IR filter 512 on opposing surfaces. Thereafter, the glass wafer may be diced into individual ones of glass plate 500 and each such glass plate 500 may be attached to a semiconductor die having a light sensor, such as semiconductor die 114. In some other examples, the relative locations of the light filters may be reversed so that IR filter 512 is on first surface 506 and diffuser filter 508 is on second surface 510.

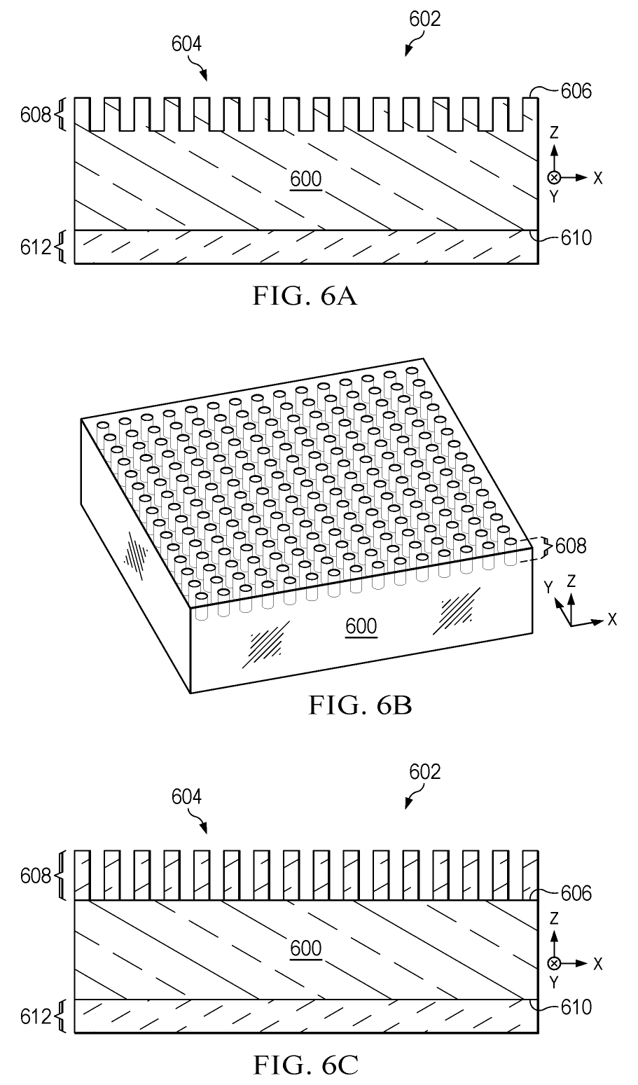

FIGS. 6A-6C are simplified views of example glass plate 600 used in an optical filter package 602 of a light sensor system 604. Glass plate 600 is substantially similar to glass plate 104 in various examples. In a first example shown in FIGS. 6A-6B, a first surface 606 of glass plate 600 includes a micro-hole filter 608, comprising blind micro-holes of less than 100 micrometers in diameter. In some examples, all the micro-holes may be approximately of the same diameter; in some other examples, some micro-holes may have different diameters from other micro-holes, depending on the desired angles of light to be transmitted across different regions in glass plate 600. In some examples, the micro-holes may be at an angle relative to first surface 606. The value of the angle may be selected according to the specific end-use application. For example, where optical filter package 602 is to be located in a configuration such that incident angle has maximum intensity at 45° relative to first surface 606, the micro-holes may be oriented at 45° relative to first surface 606.

In the example shown in the cross-sectional view of FIG. 6A and perspective view of FIG. 6B, the micro-holes are drilled (e.g., using laser drilling, etching, or other forms of fabricating micro-holes) into first surface 606. In another example shown in the cross-sectional view of FIG. 6C, the micro-holes are comprised in a film coated on first surface 606. The micro-holes may facilitate precise control of the amount and angle of light transmitted through glass plate 600. A second surface 610 of glass plate 600 may comprise another filter, for example, IR filter 612. IR filter 612 may be substantially similar to IR filter 312. In various examples, a glass wafer may be processed to generate micro-hole filter 608 and IR filter 612 on opposing surfaces. Thereafter, the glass wafer may be diced into individual ones of glass plate 600 and each such glass plate 600 may be attached to a semiconductor die having a light sensor, such as semiconductor die 114. In some other examples, the relative locations of the light filters may be reversed so that IR filter 612 is on first surface 606 and micro-hole filter 608 is on second surface 610.

In some applications, light incident on semiconductor die 114 may be required to be at specified angles within the IR spectrum of light. Such may be the case where a light sensor in semiconductor die 114 may be to detect objects at specific angles or orientations. In some such applications, glass plate 600 with the optical filters as described herein may be used suitably. In some applications, the choice to place micro-hole filter 608 on first surface 606 or second surface 610 may depend on the desired optical properties of the light transmitted through glass plate 600 relative to the effectiveness of the combination of filters. For example, in some cases, it may be more effective to place IR filter 612 on first surface 606, where effectiveness of IR filter 612 is agnostic to the incident light angle.

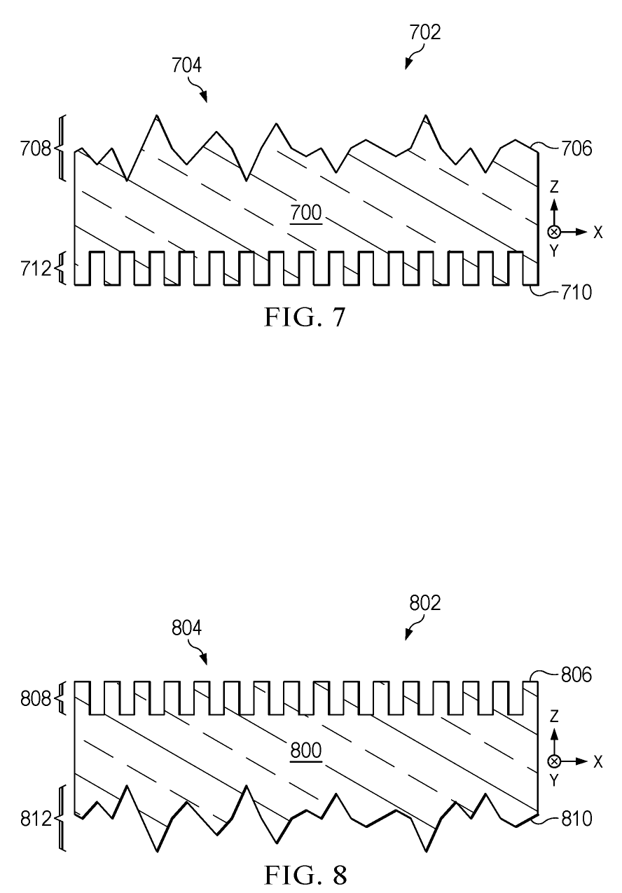

FIG. 7 is a simplified side view of a glass plate 700 used in an optical filter package 702 of a light sensor system 704. Glass plate 700 is substantially similar to glass plate 104 in various examples. In the example shown, a first surface 706 of glass plate 700 includes a diffuser filter 708. Diffuser filter 708 may comprise any of the structures shown and described with reference to FIGS. 3-5. In the specific example shown in FIG. 7, diffuser filter 708 is substantially similar to diffuser filter 308. A second surface 710 of glass plate 700 may comprise another filter, for example, micro-hole filter 712. Micro-hole filter 712 may be substantially similar to micro-hole filter 608 shown and described in reference to FIGS. 6A-6C. In various examples, a glass wafer may be processed to generate diffuser filter 708 and micro-hole filter 712 on opposing surfaces. Thereafter, the glass wafer may be diced into individual ones of glass plate 700 and each such glass plate 700 may be attached to a semiconductor die having a light sensor, such as semiconductor die 114.

FIG. 8 is a simplified side view of a glass plate 800 used in an optical filter package 802 of a light sensor system 804. Glass plate 800 is substantially similar to glass plate 104 in various examples. In the example shown, a first surface 806 of glass plate 800 includes a micro-hole filter 808. Micro-hole filter 808 may be substantially similar to micro-hole filter 608 shown and described with reference to FIGS. 6A-6C. A second surface 810 of glass plate 800 may comprise another filter, for example, diffuser filter 812. Diffuser filter 812 may comprise any of the structures shown and described with reference to FIGS. 3-5. In the specific example shown in FIG. 8, diffuser filter 812 is substantially similar to diffuser filter 308. In various examples, a glass wafer may be processed to generate micro-hole filter 808 and diffuser filter 812 on opposing surfaces. Thereafter, the glass wafer may be diced into individual ones of glass plate 800 and each such glass plate 800 may be attached to a semiconductor die having a light sensor, such as semiconductor die 114.

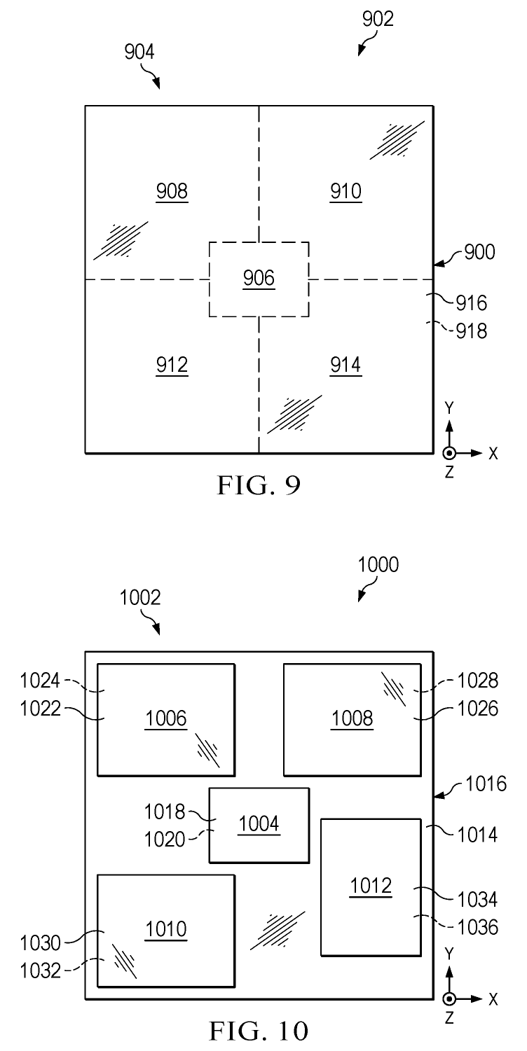

FIG. 9 is a simplified plan view of a glass plate 900 used in an optical filter package 902 of a light sensor system 904. Glass plate 900 may comprise a plurality of regions 906-914 having different types of optical filters on first surface 916 and second surface 918. In some examples, each region in the plurality of regions 906-914 may have a different combination of filters on opposing surfaces compared to other ones in the plurality. In one example, region 906 may comprise an IR filter on first surface 916 and another IR filter on second surface 918; region 908 may comprise a diffuser filter on first surface 916 and an IR filter on second surface 918, for example, similar to the structure shown in any one of FIGS. 3-5; region 910 may comprise a micro-hole filter on first surface 916 and an IR filter on second surface 918, for example, similar to the structure shown in any one of FIGS. 6A-6C; region 912 may comprise a diffuser filter on first surface 916 and a micro-hole filter on second surface 918, for example, similar to the structure shown in FIG. 7; and region 914 may comprise a micro-hole filter on first surface 916 and a diffuser filter on second surface 918, for example, similar to the structure shown in FIG. 8.

In the drawing, regions 906-914 are shown to be contiguous, with edges of each region touching edges of adjacent regions. In other examples, regions 906-914 may not be contiguous, for example, they may be separated by other regions having no filters on first surface 916 and/or second surface 918. Furthermore, in the figure, regions 906-914 are shown as regular rectangles; such is merely for ease of illustration and not as a limitation. Regions 906-914 may be of any suitable shape and different size, depending on the end application. In addition, any number of different regions may be provisioned in glass plate 900 within the scope of the various examples. In some such examples, some regions may be similar to each other in configuration (e.g., structure), shape, and/or size. In some other such examples, each region may be different from all other regions in configuration, shape, and/or size.

FIG. 10 is a simplified plan view of some components of an optical filter package 1000 of a light sensor system 1002. A plurality of glass plates 1004-1012 may be coupled to third surface 1014 of a semiconductor die 1016. In various examples, a plane along a surface of the plurality of glass plates 1004-1012 is coplanar and parallel to a surface of semiconductor die 1016. Semiconductor die 1016 may be substantially similar to semiconductor die 114, and may also include light sensors such as light sensor 115. Each glass plate 1004-1012 may comprise a corresponding combination of filters on respective first surface and second surface. For example, glass plate 1004 may comprise an IR filter on first surface 1018 and another IR filter on second surface 1020; glass plate 1006 may comprise a diffuser filter on first surface 1022 and an IR filter on second surface 1024, for example, similar to the structure shown in any one of FIGS. 3-5; glass plate 1008 may comprise a micro-hole filter on first surface 1026 and an IR filter on second surface 1028, for example, similar to the structure shown in any one of FIGS. 6A-6C; glass plate 1010 may comprise a diffuser filter on first surface 1030 and a micro-hole filter on second surface 1032, for example, similar to the structure shown in FIG. 7; and glass plate 1012 may comprise a micro-hole filter on first surface 1034 and a diffuser filter on second surface 1036, for example, similar to the structure shown in FIG. 8.

In the drawing, glass plates 1004-1012 are shown as regular rectangles; such is merely for ease of illustration and not as a limitation. Glass plates 1004-1012 may be of any suitable shape (e.g., hexagon, triangle, irregular shaped, etc.) and different size, depending on the end application. In various implementations, the spacing between individual glass plates 1004-1012 may be determined by handling accuracy and other manufacturing concerns beyond the scope of the present disclosure. In addition, any number of different glass plates may be provisioned on third surface 1014 of semiconductor die 1016 within the scope of the various examples. In some such examples, some glass plates may be similar to each other in configuration (e.g., structure), shape, and/or size. In some other such examples, each glass plate may be different from all other glass plates in configuration, shape, and/or size.

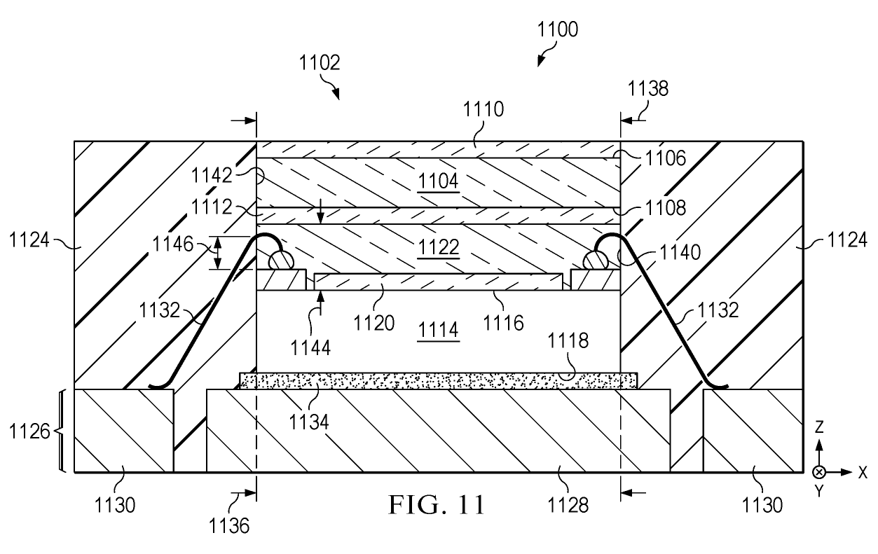

FIG. 11 is a simplified diagram illustrating a cross-sectional view of an example optical filter package 1100 used in a light sensor system 1102. Optical filter package 1100 comprises a glass plate 1104 having a first surface 1106 and a second surface 1108 opposite to first surface 1106. First surface 1106 has a first filter 1110, and second surface 1108 has a second filter 1112 different from first filter 1110. Optical package 1100 further includes a semiconductor die 1114 having a third surface 1116 and a fourth surface 1118 opposite to third surface 1116. Semiconductor die 1114 may be substantially similar to semiconductor die 114, and may also include light sensors such as light sensor 115. At least a portion of third surface 1116 has a color filter 1120. An optically transparent adhesive 1122 is in contact with second surface 1108 of glass plate 1104 and third surface 1116 of semiconductor die 1114. An optically opaque mold compound 1124 peripherally surrounds glass plate 1104 and semiconductor die 1114 such that first filter 1110 is exposed. A substrate 1126 comprises a first region 1128 proximate to fourth surface 1118 of semiconductor die 1114. Substrate 1126 further comprises a second region 1130 to electrically couple to semiconductor die 1114 by wire-bonds 1132. An adhesive 1134 is in contact with substrate 1126 and fourth surface 1118 of semiconductor die 1114. In some examples, as in the one shown in the figure, a first footprint 1136 of semiconductor die 1114 may be approximately same as a second footprint 1138 of glass plate 1104. In addition, peripheral edge 1140 of optically transparent adhesive 1122 may be substantially flush with peripheral edge 1142 of glass plate 1104 (e.g., footprint of optically transparent adhesive 1122 may be approximately equal to footprint 1138 of glass plate 104 and footprint 1136 of semiconductor die 1114).

Wire-bonds 1132 may be partially embedded in optically transparent adhesive 1122. A thickness 1144 of optically transparent adhesive 1122 may be selected to be larger than a height 1146 of wire-bonds 1132 over third surface 1116 of semiconductor die 1114. Furthermore, the material of optically transparent adhesive 1122 may be selected to have liquidus properties and B-stage cured when applied to glass plate 1104. When heated after placing glass plate 1104 over semiconductor die 1114, the material liquifies further, spreading over and around wire-bonds 1132 over third surface 1116. Upon curing completely, the material solidifies, encapsulating the ends of wire-bonds 1132 under glass plate 1104.

In the example shown, optical filter package 1100 is a QFN package or DFN package, exposing regions 1128 and 1130 of substrate 1126 opposite to first surface 1106 of glass plate 1104. Various other package formats may also be used without departing from the scope of the examples described herein. Substrate 1126 may be mounted to a PCB such that regions 1128 and 1130 of substrate 1126 opposite to first surface 1106 of glass plate 1104 are electrically and/or thermally bonded to the PCB. During operation, light may be incident on first surface 1106 and detected suitably by circuits in semiconductor die 1114.

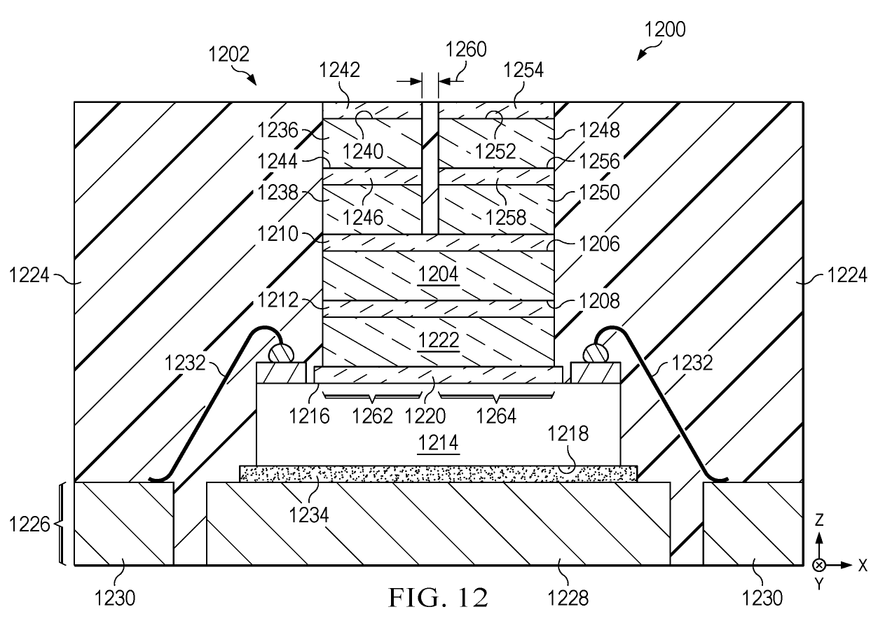

FIG. 12 is a simplified diagram illustrating a cross-sectional view of an example optical filter package 1200 used in a light sensor system 1202. Optical filter package 1200 comprises a glass plate 1204 having a first surface 1206 and a second surface 1208 opposite to first surface 1206. First surface 1206 has a first filter 1210, and second surface 1208 has a second filter 1212 different from first filter 1210. Optical package 1200 further includes a semiconductor die 1214 having a third surface 1216 and a fourth surface 1218 opposite to third surface 1216. Semiconductor die 1214 may be substantially similar to semiconductor die 114, and may also include light sensors such as light sensor 115. At least a portion of third surface 1216 has a color filter 1220. An optically transparent adhesive 1222 is in contact with second surface 1208 of glass plate 1204 and third surface 1216 of semiconductor die 1214. An optically opaque mold compound 1224 peripherally surrounds glass plate 1204 and semiconductor die 1214. A substrate 1226 comprises a first region 1228 proximate to fourth surface 1218 of semiconductor die 1214. Substrate 1226 further comprises a second region 1230 to electrically couple to semiconductor die 1214 by wire-bonds 1232. An adhesive 1234 is in contact with substrate 1226 and fourth surface 1218 of semiconductor die 1214.

In various examples, a plurality of additional glass plates may be coupled to glass plate 1204 in a tiered structure, such additional glass plate having different combinations of optical filters. For example, a glass plate 1236 may be coupled by optically transparent adhesive 1238 to a portion of glass plate 1204.First surface 1240 of glass plate 1236 has a first filter 1242, and second surface 1244 has a second filter 1246 different from first filter 1242. Optically transparent adhesive 1238 may be between first surface 1206 of glass plate 1204 and second surface 1244 of glass plate 1236. Likewise, another glass plate 1248 may be coupled by optically transparent adhesive 1250 to another portion of glass plate 1204. First surface 1252 of glass plate 1248 has a first filter 1254, and second surface 1256 has a second filter 1258 different from first filter 1254. Optically transparent adhesive 1250 may be between first surface 1206 of glass plate 1204 and second surface 1256 of glass plate 1248.

Optically opaque mold compound 1224 peripherally surrounds glass plates 1236 and 1248 such that first filters 1242 and 1254 of respective glass plates 1236 and 1248 are exposed. In some examples, a gap 1260 may be present between glass plates 1236 and 1248. In other examples, gap 1260 may be negligible or absent so that adjacent peripheral sides of glass plates 1236 and 1248 may touch each other. The presence of gap 1260 may depend on handling tolerances and other manufacturing concerns beyond the scope of the embodiments. In many cases, peripheral edges of optically transparent adhesives 1222, 1238, and 1250 may be flush with edges of the respective glass plates 1204, 1236 and 1248 based on the manufacturing process. For example, in some manufacturing processes, the optically transparent adhesive may be applied as a film on a glass wafer; the glass wafer may thereafter be diced into individual glass plates, mounted appropriately on semiconductor die 1214 and to other glass plates as described herein, and subjected to a curing process whereby the optically transparent adhesive is cured. Glass plates 1204, 1236 and 1248 may be derived from different glass wafers in some examples.

In some examples, a single glass plate may be mounted on glass plate 1204 instead of multiple glass plates 1236 and 1248. In some such examples, the footprint of the additional glass plate may be the same as footprint of glass plate 1204. In some other such examples, the footprint of the additional glass plate may be smaller than the footprint of glass plate 1204. The selection of multiple versus single glass plate and the different types of filters of each glass plate may be based on the optical requirements of the light incident on the appropriate light sensors in semiconductor die 1214. For example, light incident on region 1262 of third surface 1216 of semiconductor die 1214 may be desired to have a first set of optical properties (e.g., green wavelength, light incident on surface 1240 at a first angle, maximum predetermined intensity); light incident on region 1264 of third surface 1216 of semiconductor die 1214 may be desired to have a second set of optical properties (e.g., red wavelength, light incident on surface 1252 at a second angle, minimum predetermined intensity); and so on. These optical requirements may be based on the functionalities of the underlying optical circuits in semiconductor die 1214, beyond the scope of the present disclosure. Thus, the combination of filters 1242, 1246, 1210, 1212 and 1220 over region 1262 may be different from the combination of other filters 1254, 1258, 1210, 1212 and 1220 over region 1264. In some cases, one or more filters in the stack may be absent. For example, the stack of filters over region 1262 may not have color filter 1220 and only one or more IR filters may be present in the stack of filters, whereas the other stack of filters over region 1264 may include color filters and one or more diffuser filters and micro-hole filters. Thus, various combinations of filters may be placed at the package level on semiconductor die 1214 based on particular needs.

In the example shown, optical filter package 1200 is a QFN package or DFN package format, exposing regions 1228 and 1230 of substrate 1226. Various other package formats may also be used without departing from the scope of the examples described herein. Substrate 1226 may be mounted to a PCB such that regions 1228 and 1230 of substrate 1226 are electrically and/or thermally bonded to the PCB. During operation, light incident on light sensor system 1202 may be transmitted through various filters 1242, 1254, 1246, 1258, 1210, 1212 and 1220 to be detected suitably by circuits in semiconductor die 1214.

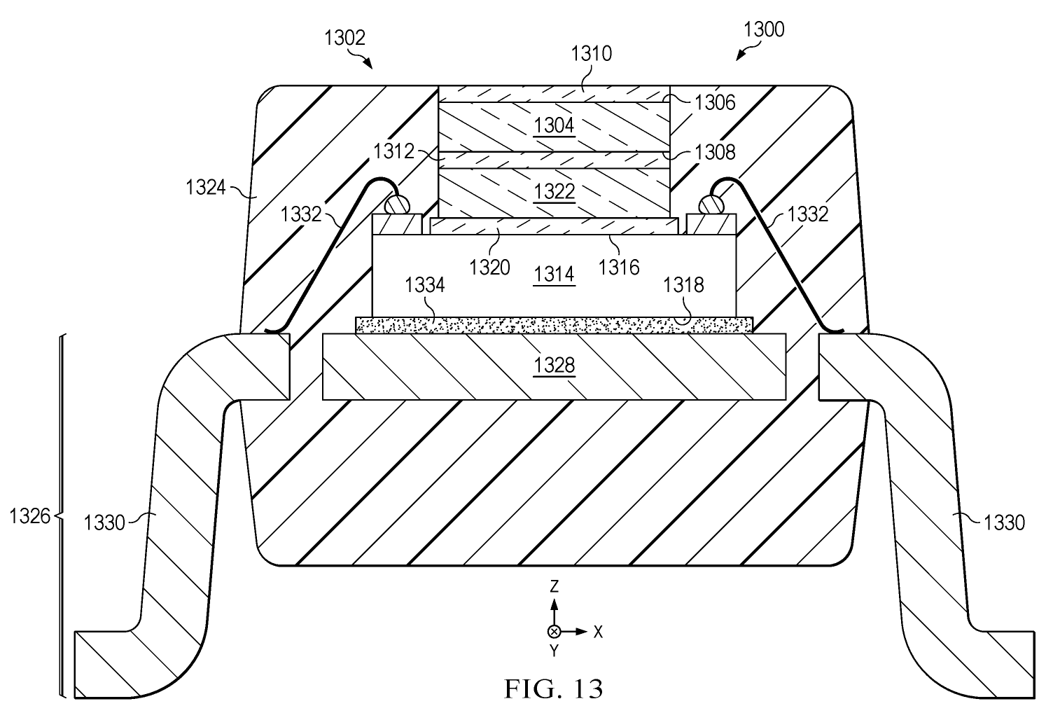

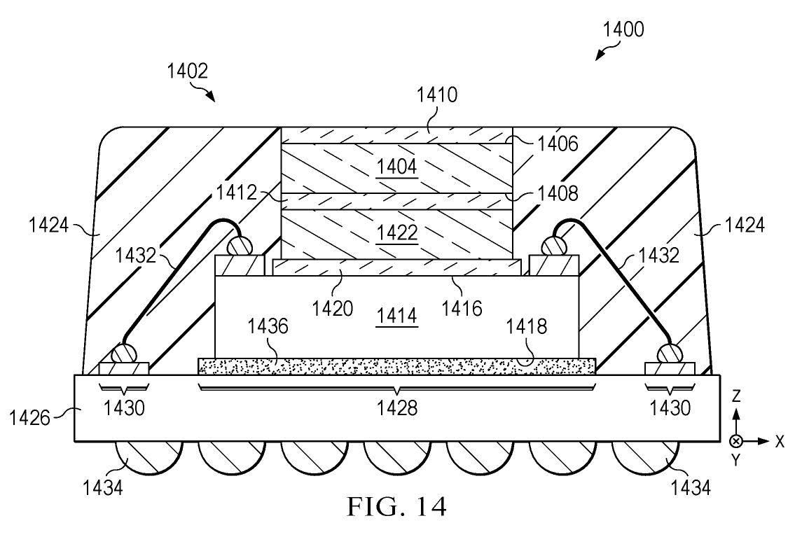

FIG. 13 is a simplified diagram illustrating a cross-sectional view of an example optical filter package 1300 used in a light sensor system 1302. Optical filter package 1300 comprises a glass plate 1304 having a first surface 1306 and a second surface 1308 opposite to first surface 1306. First surface 1306 has a first filter 1310, and second surface 1308 has a second filter 1312 different from first filter 1310. Optical package 1300 further includes a semiconductor die 1314 having a third surface 1316 and a fourth surface 1318 opposite to third surface 1316. Semiconductor die 1314 may be substantially similar to semiconductor die 114, and may also include light sensors such as light sensor 115. At least a portion of third surface 1316 has a color filter 1320. An optically transparent adhesive 1322 is in contact with second surface 1308 of glass plate 1304 and third surface 1316 of semiconductor die 1314. An optically opaque mold compound 1324 peripherally surrounds glass plate 1304 and semiconductor die 1314. A substrate 1326 comprises a first region 1328 proximate to fourth surface 1318 of semiconductor die 1314. Substrate 1326 further comprises a second region 1330 to electrically couple to semiconductor die 1314 by wire-bonds 1332. In the example shown, optical filter package 1300 is configured as a leadframe. In such examples, first region 1328 may comprise a die pad and second region 1330 may comprise leadfingers. An adhesive 1334 is in contact with substrate 1326 and fourth surface 1318 of semiconductor die 1314.

FIG. 14 is a simplified diagram illustrating a cross-sectional view of an example optical filter package 1400 used in a light sensor system 1402. Optical filter package 1400 comprises a glass plate 1404 having a first surface 1406 and a second surface 1408 opposite to first surface 1406. First surface 1406 has a first filter 1410, and second surface 1408 has a second filter 1412 different from first filter 1410. Optical package 1400 further includes a semiconductor die 1414 having a third surface 1416 and a fourth surface 1418 opposite to third surface 1416. Semiconductor die 1414 may be substantially similar to semiconductor die 114, and may also include light sensors such as light sensor 115. At least a portion of third surface 1416 has a color filter 1420. An optically transparent adhesive 1422 is in contact with second surface 1408 of glass plate 1404 and third surface 1416 of semiconductor die 1414. An optically opaque mold compound 1424 peripherally surrounds glass plate 1404 and semiconductor die 1414. A substrate 1426 comprises a first region 1428 proximate to fourth surface 1418 of semiconductor die 1414. Substrate 1426 further comprises a second region 1430 to electrically couple to semiconductor die 1414 by wire-bonds 1432. In the example shown, optical filter package 1400 is configured as a ball grid array package, with solder balls 1434 on a surface of substrate 1426 opposite from semiconductor die 1414. In such examples, second region 1430 may comprise bond pads on substrate 1426. Substrate 1426 may comprise builtup layers of organic dielectric and embedded electrical conductors (e.g., metal layers and conductive vias between layers of organic dielectric). An adhesive 1436 is in contact with substrate 1426 and fourth surface 1418 of semiconductor die 1414.

Although the present disclosure has described in detail particular arrangements and configurations, these example configurations and arrangements may be changed significantly without departing from the scope of the present disclosure. For example, although the present disclosure has been described with reference to optically opaque mold compounds, the same configuration and arrangements may be applicable to other types of mold compounds, such as transparent mold compounds. Moreover, although the optical filter packages and light sensors have been illustrated with reference to particular elements that facilitate the optical light processing functionalities, these elements and operations may be replaced by any other suitable architecture for non-optical processing, such as electrical signal processing.

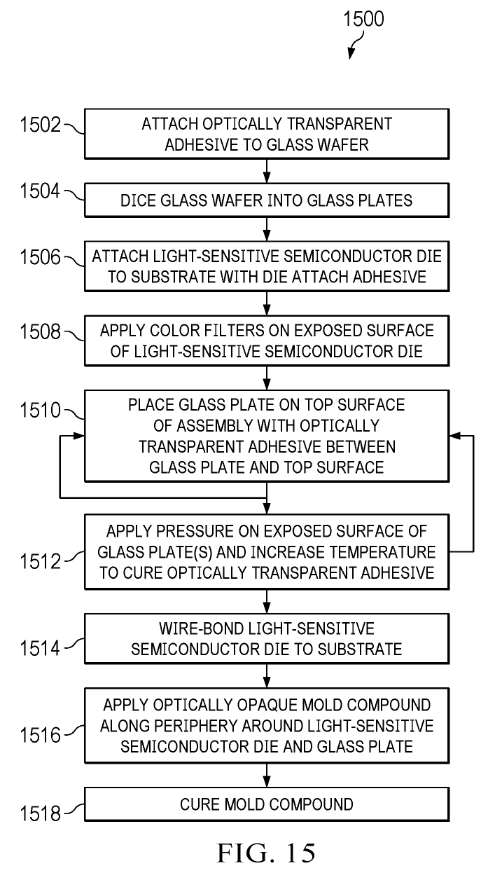

FIG. 15 is a simplified flow diagram illustrating example operations 1500 associated with manufacturing an optical filter package, such as optical filter package 100. At 1502, optically transparent adhesive 122 may be applied to a glass wafer comprising first filter 110 on first surface 106 and second filter 112 on second surface 108. In some examples, optically transparent adhesive 122 may be in the form of a film; in some other examples, optically transparent adhesive 122 may be in the form of a liquid that is applied uniformly and dried without curing. At 1504, the glass wafer may be diced into individual ones of glass plate 104. The size of the dices may be based on the size of semiconductor die 114 to which they are to be attached. In some examples, the footprint of glass plate 104 is smaller than the footprint of semiconductor die 114.

At 1506, semiconductor die 114 may be attached to substrate 126 with adhesive 134. At 1508, color filter 120 may be applied on exposed surface, i.e., third surface 116, of semiconductor die 114. In some examples, the operation may be performed at wafer-scale on multiple ones of semiconductor die 114 on one or more wafers simultaneously. Thereafter, individual ones of semiconductor die 114 may be diced (e.g., cut and separated from the wafer). In some examples, the operation at 1508 may precede the operation at 1506. In some examples, the operation at 1508 may precede the operation at 1502. At 1510, glass plate 104 may be placed on top surface of the die assembly, i.e., third surface 116 of semiconductor die 114 with optically transparent adhesive 122 between glass plate 104 and third surface 116. The operation at 1510 may be repeated for additional glass plates to be attached on top of glass plate 104, for example, as in the arrangement shown in FIG. 12. After all glass plates have been placed as desired, at 1512, pressure may be applied on the topmost surface of the exposed glass plate and optically transparent adhesive 122 may be subjected to a curing process (e.g., by heating, using ultraviolet rays, drying, etc.). During this process, optically transparent adhesive 122 may liquefy and flow under the pressure (or temperature) to conform to the topography created by color filter 120 on third surface 116 of semiconductor die 114. For example, optically transparent adhesive 122 conforms to topological variations of the surface on semiconductor die 114. In some examples, instead of placing all glass plates one on top of another and then applying pressure to the topmost surface and heating, the attachment of glass plates may proceed one by one. Thus, after one glass plate is attached by curing the optically transparent adhesive, the next layer of glass plate is attached, and the adhesive is cured. The process may continue until all the glass plates are attached as desired. In some examples where the topology of third surface 116 of semiconductor die 114 is within a predetermined range (e.g., surface has uniform topology, color filters 120 have substantially same thickness, etc.), at 1512, pressure may not be applied, and instead, optically transparent adhesive 122 may be subjected to the curing process directly.

After optically transparent adhesive 122 is cured, at 1514, semiconductor die 114 may be wire-bonded to substrate 126. At 1516, optically opaque mold compound 124 may be applied along the periphery around semiconductor die 114 and glass plate 104. In some examples, optically opaque mold compound 124 is added by film assisted molding process. At 1518, optically opaque mold compound 124 may be cured suitably (e.g., by heat or ultraviolet energy).

Although FIG. 15 illustrates various operations performed in a particular order, this is simply illustrative, and the operations discussed herein may be reordered and/or repeated as suitable. Further, additional operations which are not illustrated may also be performed without departing from the scope of the present disclosure. Also, various ones of the operations discussed herein with respect to FIG. 15 may be modified in accordance with the present disclosure to manufacture optical filter package 100 as disclosed herein. For example, to create a structure as shown in FIG. 11, the wirebonding operation at 1514 may be performed before placing glass plate 104 on top surface of the die assembly at operation 1510. In another example, to create a structure as shown in FIG. 1, the sequence of the wirebonding operation at 1514 relative to operation at 1510 may be based on other constraints, such as the size of the wirebonding apparatus so as not to touch glass plate 104, or the pick-and-place accuracy of the apparatus that places glass plate 104 on the top surface of the die assembly to prevent touching wirebonds already in place, etc. Although various operations are illustrated in FIGS. 15-16 once each, the operations may be repeated as often as desired.

It is important to note that the operations described with reference to the preceding figures illustrate only some of the possible scenarios that may be implemented to manufacture optical filter package 100. Some of these operations may be deleted or removed where appropriate, or these steps may be modified or changed considerably without departing from the scope of the discussed concepts. In addition, the timing of these operations may be altered considerably and still achieve the results taught in this disclosure. The preceding operational flows have been offered for purposes of example and discussion.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. An optical filter package, comprising:
a glass plate having a first surface and a second surface opposite to the first surface, wherein the first surface has a first filter, and the second surface has a second filter different from the first filter;
a semiconductor die including a light sensor and having a third surface and a fourth surface opposite to the third surface, wherein at least a portion of the third surface has a third filter; and
an optically transparent adhesive in contact with the second surface of the glass plate and the third surface of the semiconductor die.

2. The optical filter package of claim 1, wherein the first filter and the second filter are one of: a diffuser filter, a micro-hole filter, or an infrared filter.

3. The optical filter package of claim 1, wherein the glass plate comprises a plurality of different regions in a plan view, each region having a different combination of filters on the first surface and the second surface.

4. The optical filter package of claim 1, further comprising a plurality of glass plates, each glass plate having a different combination of filters on opposing surfaces parallel to the third surface.

5. The optical filter package of claim 4, wherein planes along a surface of each glass plate are coplanar.

6. The optical filter package of claim 4, wherein in the plurality of glass plates, some glass plates are stacked on some other glass plates.

7. The optical filter package of claim 1, wherein:
the glass plate has a first footprint,
the semiconductor die has a second footprint, and
the first footprint is smaller than the second footprint.

8. The optical filter package of claim 1, further comprising a plurality of color filters on the third surface of the semiconductor die, wherein in the plurality of color filters:
at least two are to filter different colors,
at least one has a first thickness, and
at least another has a second thickness different from the first thickness.

9. The optical filter package of claim 1, wherein the third filter is between the light sensor and the optically transparent adhesive.

10. An optical filter package, comprising:
a glass plate having a first surface and a second surface opposite to the first surface, wherein the first surface has a first filter, and the second surface has a second filter;
a semiconductor die including a light sensor and having a third surface and a fourth surface opposite to the third surface, wherein at least a portion of the third surface has a third filter;
an optically transparent adhesive in contact with the second surface of the glass plate and the third surface of the semiconductor die;
an optically opaque mold compound peripherally surrounding the glass plate and the semiconductor die such that the first surface of the glass plate is exposed;
a substrate comprising a first region proximate to the fourth surface of the semiconductor die, and a second region to electrically couple to the semiconductor die; and
an adhesive mechanically coupling the substrate to the fourth surface of the semiconductor die.

11. The optical filter package of claim 10, wherein the first filter or the second filter comprises material deposited on the first surface or the second surface.

12. The optical filter package of claim 10, wherein the first filter or the second filter comprises shapes etched on the first surface or the second surface.

13. The optical filter package of claim 10, further comprising a plurality of glass plates, each glass plate having a different combination of filters on opposing surfaces parallel to the third surface.

14. The optical filter package of claim 10, wherein the optical filter package is a quad flat no lead (QFN) package.

15. The optical filter package of claim 10, wherein the substrate is a leadframe.

16. The optical filter package of claim 10, wherein the substrate comprises organic dielectric material and embedded electrical conductors.

17. A method of making an integrated filter package, comprising:
attaching a film of optically transparent adhesive to a glass wafer, the glass wafer including different filters on opposing surfaces;
dicing the glass wafer into individual glass plates, each glass plate including a portion of the film of optically transparent adhesive;
placing a glass plate on a top surface of an assembly comprising a semiconductor die including a light sensor, wherein:
a surface of the semiconductor die proximate to the glass plate includes at least one other filter, and
the portion of the film of optically transparent adhesive is between the glass plate and the surface of the semiconductor die;
applying pressure on an exposed surface of the glass plate and curing the portion of the film of optically transparent adhesive;
electrically coupling the semiconductor die to a substrate;
applying an optically opaque mold compound along a periphery of the semiconductor die and the glass plate; and
curing the optically opaque mold compound.

18. The method of claim 17, further comprising attaching the semiconductor die to the substrate with an adhesive.

19. The method of claim 17, wherein the optically opaque mold compound is applied by film assisted molding process.

20. The method of claim 17, further comprising:
placing a plurality of glass plates on the semiconductor die, each glass plate having a different combination of filters on opposing surfaces parallel to the surface of the semiconductor die; and
applying pressure on all exposed surfaces of the plurality of glass plates and increasing temperature until each portion of the film of optically transparent adhesive between the plurality of glass plates and the semiconductor die is cured.
